(19) United States
(12) Patent Application Publication
(10) Pub. No.: US 2025/0101590 A1
(43) Pub. Date: Mar. 27, 2025

(54) SUBSTRATE PROCESSING APPARATUS AND MANUFACTURING METHOD THEREOF

(71) Applicant: SEMES CO., LTD., Cheonan-si (KR)

(72) Inventors: Jun Seok PARK, Gyeonggi-do (KR); Yong Jun BAE, Chungcheongnam-do (KR); Ja Myung GU, Chungcheongnam-do (KR); Asatur KHURSHUDYAN, Chungcheongnam-do (KR); Shant ARAKELYAN, Chungcheongnam-do (KR)

(73) Assignee: SEMES CO., LTD., Cheonan-si (KR)

(21) Appl. No.: 18/800,442

(22) Filed: Aug. 12, 2024

(30) Foreign Application Priority Data
Sep. 22, 2023 (KR) 10-2023-0126769

(51) Int. Cl. C23C 16/458; C23C 16/455

(52) U.S. Cl. CPC C23C 16/4581; C23C 16/45565

(57) ABSTRACT

Provided is a substrate processing apparatus. The substrate processing apparatus of the present invention comprises a support unit provided in a processing space for processing a substrate and for supporting the substrate, wherein the support unit comprises a puck having a first thermal conductivity and having a concave groove formed thereon; and a block provided in the concave groove and having a second thermal conductivity different from the first thermal conductivity.

This application claims the benefit of Korean Patent Application No. 10-2023-0126769, filed on Sep. 22, 2023, in the Korean Intellectual Property Office, the disclosure of which is incorporated herein by reference in its entirety.

### BACKGROUND

### 1. Field

The present invention relates to a substrate processing apparatus and a method of manufacturing the substrate processing apparatus.

### 2. Description of the Related Art

The process of manufacturing a semiconductor comprises a deposition process to form a film on a semiconductor wafer (hereinafter referred to as a substrate), a chemical/mechanical polishing process to flatten the film, a photolithography process to form a photoresist pattern on the film, an etching process to form a film into a pattern with electrical characteristics using a photoresist pattern, an ion implantation process to inject specific ions into a predetermined region of the substrate, a cleaning process to remove impurities on the substrate, and an inspection process to inspect the surface of the substrate on which the film or the pattern is formed.

The etching process is a process for removing exposed regions of the photoresist pattern formed by the photolithography process on the substrate. Types of etching processes can be divided into dry etching and wet etching.

The dry etching process forms an electric field by applying high-frequency power to the upper and lower electrodes installed at a predetermined distance in a sealed internal space where the etching process is performed, and applies an electric field to the reactive gas supplied into the sealed space to activate the reactive gas to create a plasma state. And then, the ions in the plasma etch the substrate located on the lower electrode.

At this time, it is necessary to form plasma uniformly over the entire upper surface of the substrate. A ring assembly is provided to uniformly form plasma over the entire upper surface of the substrate. The ring assembly is installed to surround the edge of the support unit supporting the substrate.

Additionally, the temperature of the substrate may be non-uniform depending on the region, and if the temperature is non-uniform, problems with poor substrate yield may occur.

### SUMMARY

The technical problem to be solved by the present invention is to provide a substrate processing apparatus and a method of manufacturing the substrate processing apparatus that can improve the temperature uniformity of the support unit.

The objects of the present invention are not limited to the objects mentioned above, and other objects not mentioned will be clearly understood by those skilled in the art from the description below.

The technical objects of the present invention are not limited to the technical objects mentioned above, and other technical objects not mentioned will be clearly understood by those skilled in the art from the description below.

One aspect of the substrate processing apparatus of the present invention for achieving the above technical object comprises a support unit provided in a processing space for processing a substrate and for supporting the substrate, wherein the support unit comprises a puck having a first thermal conductivity and having a concave groove formed thereon, and a block provided in the concave groove and having a second thermal conductivity different from the first thermal conductivity.

One aspect of the manufacturing method of the substrate processing apparatus of the present invention for achieving the above other object comprises, in a method for manufacturing a substrate processing apparatus that performs a plasma etching process, providing a support chuck provided in a processing space for processing a substrate, and for supporting the substrate, wherein providing the support chuck comprises preparing a puck having a first thermal conductivity, machining a concave groove in the puck, and providing a powder having an alumina component ratio having a second thermal conductivity higher than the first thermal conductivity to the concave groove.

Another aspect of the substrate processing apparatus of the present invention for achieving the above technical object comprises a chamber, in which a processing space for processing a substrate is formed, a gas supply unit for supplying process gas to the processing space, a shower head provided above the processing space and for spraying the process gas supplied from the gas supply unit into the processing space, a support unit provided in the processing space and for supporting the substrate, a first heat transfer medium supply unit for supplying heat transfer medium to the support unit at a first fluid pressure, and a second heat transfer medium supply unit for supplying the heat transfer medium to the support unit at a second fluid pressure different from the first fluid pressure, wherein the support unit comprises a first circulation passage including a first heat transfer medium passage penetrating the support unit to supply a heat transfer medium to the substrate and connected to the first heat transfer medium supply unit, and a second heat transfer medium passage connected to the second heat transfer medium supply unit, a support chuck including a puck having a first alumina component ratio, a first thermal conductivity, and a concave groove formed therein, and a block provided in the concave groove, having a second alumina component ratio different from the first alumina component ratio, and a second thermal conductivity higher than the first thermal conductivity, and a body provided below the puck, made of aluminum, and having a second circulation passage through which a temperature control fluid moves.

Specific details of other embodiments are included in the detailed description and drawings.

### BRIEF DESCRIPTION OF THE DRAWINGS

These and/or other aspects will become apparent and more readily appreciated from the following description of the embodiments, taken in conjunction with the accompanying drawings in which:

FIG. 1 is a diagram illustrating a substrate processing apparatus according to a first embodiment of the present invention;

FIG. 2 is a diagram illustrating region A of FIG. 1;

FIG. 3 is a diagram illustrating a support unit of a substrate processing apparatus according to a second embodiment of the present invention;

FIG. 4 is a flowchart illustrating a method of manufacturing a substrate processing apparatus according to some embodiments of the present invention;

FIG. 5 is a diagram illustrating a state, in which a puck is provided in a substrate processing apparatus according to some embodiments of the present invention;

FIG. 6 is a diagram illustrating a state, in which a concave groove is machined into a puck of a substrate processing apparatus according to some embodiments of the present invention;

FIG. 7 is a diagram illustrating a state, in which a block is formed on a puck of a substrate processing apparatus according to some embodiments of the present invention; and

FIG. 8 is a diagram illustrating a state, in which a first circulation passage is formed in a support chuck of a substrate processing apparatus according to some embodiments of the present invention.

### DETAILED DESCRIPTION

Hereinafter, preferred embodiments of the present invention will be described in detail with reference to the attached drawings. The advantages and features of the present invention and methods for achieving them will become clear by referring to the embodiments described in detail below along with the accompanying drawings. However, the present invention is not limited to the embodiments disclosed below and may be implemented in various different forms. The present embodiments are merely intended to ensure that the disclosure of the present invention is complete, and provided to fully inform those skilled in the art on the scope of the invention, and the present invention is only defined by the scope of the claims. Like reference numerals refer to like elements throughout the specification.

The terminology used herein is for describing embodiments and is not intended to limit the invention. As used herein, singular forms also include plural forms, unless specifically stated otherwise in the context. As used herein, “comprises” and/or “comprising” does not rule out the addition or the presence of one or more other components, steps, operations and/or elements.

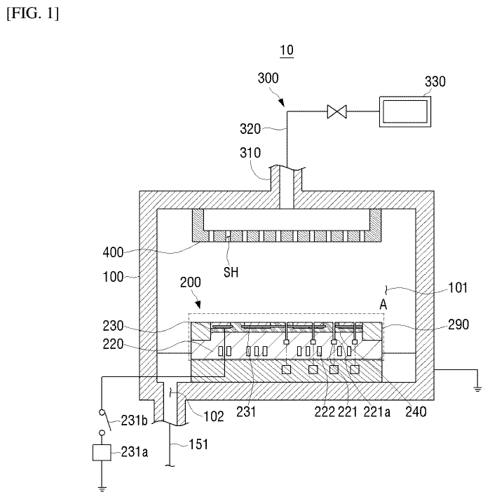

FIG. 1 is a diagram illustrating a substrate processing apparatus according to a first embodiment of the present invention.

Referring to FIG. 1, the substrate processing apparatus 10 according to an embodiment of the present invention may include a chamber 100, a support unit 200, a gas supply unit 300, and a shower head 400. The substrate processing apparatus 10 may process the substrate W using plasma. Exemplarily, the substrate processing apparatus 10 may perform an etching process on the substrate W.

The chamber 100 may provide a processing space 101 therein where a substrate processing process is performed. For example, the chamber 100 may have a cylindrical shape. The chamber 100 may be provided in a shape, in which the processing space 101 is sealed. The chamber 100 may be made of a metal material such as aluminum and may be grounded.

An exhaust hole 102 may be formed on the bottom surface of the chamber 100. The exhaust hole 102 may be connected to the exhaust line 151. Reaction by-products generated during the process and gas remaining in the internal space of the chamber 100 may be discharged to the outside through the exhaust hole 102 and the exhaust line 151. Through the exhaust process, the interior of the chamber 100 may be reduced to a predetermined pressure, and for example, a vacuum atmosphere may be formed.

A support unit 200 may be located inside the chamber 100. The support unit 200 may support the substrate W. The support unit 200 may be provided as an electrostatic chuck that adsorbs the substrate W using electrostatic force. Alternatively, the support unit 200 may support the substrate W in various ways, such as mechanical clamping. Hereinafter, an example, in which the support unit 200 is provided as an electrostatic chuck, will be described.

As an example, the support unit 200 may include a body 220, a support chuck 230, and a ring assembly 290.

The body 220 may have a support chuck 230 located at the top. The body 220 may be made of a metal material such as aluminum. A step may be formed on the upper surface of the body 220 so that the center region is located higher than the edge region. The upper center region of the body 220 may have the same area as the bottom surface of the support chuck 230. And the body 220 may be bonded to the bottom surface of the support chuck 230 by the bonding unit 240. The bonding unit 240 may be provided as an adhesive layer made of silicon, but is not limited thereto.

The body 220 may be electrically connected to a separate power source (not shown). The power source connected to the body 220 may be provided as a high-frequency power source that generates high-frequency power such as RF (high-voltage alternating current power). The body 220 that receives high-frequency power from a power source may function as an electrode.

In addition, a first circulation passage 221, a first supply passage 221a, and a second circulation passage 222 may be formed inside the body 220.

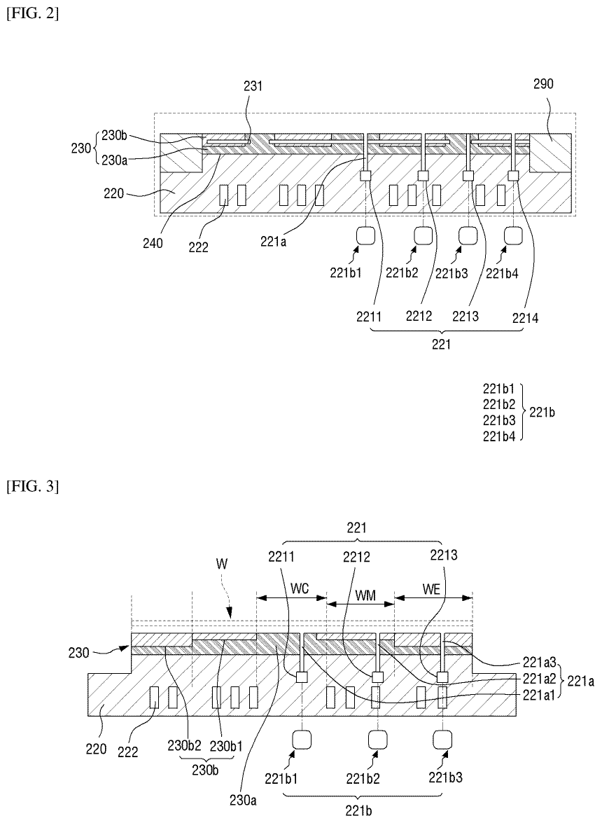

The first circulation passage 221 may serve as a passage through which a heat transfer medium circulates. For example, the first circulation passage 221 may be arranged so that ring-shaped passages with different radii have the same center, and each first circulation passage 221 is separated from each other so that individual heat transfer media can pass through. This is explained with reference to FIG. 2.

The first circulation passage 221 may be connected to a heat transfer medium storage unit (reference numeral not shown) through a heat transfer medium supply line (reference numeral not shown). A heat transfer medium may be stored in the heat transfer medium storage unit. The heat transfer medium may be an inert gas such as helium gas. Helium gas may be supplied to the first circulation passage 221 through a heat transfer medium supply line. Helium gas passing through the first circulation passage 221 may serve as a medium for transferring heat of the substrate W. That is, the substrate W can be cooled by helium gas.

A plurality of first supply passages 221a may be provided, and the first supply passages 221a may extend upward from the first circulation passage 221. For example, the first supply passage 221a may supply a heat transfer medium to the bottom surface of the substrate W by penetrating the body 220 and the support chuck 230. In addition, the first supply passage 221a and the first circulation passage 221 may be provided as a passage for recovering the heat transfer medium after the etching of the substrate W is completed.

That is, after the helium gas is supplied to the bottom surface of the substrate W through the first circulation passage 221 and the first supply passage 221a, it may be recovered to the heat transfer medium storage unit through the first supply passage 221a and the first circulation passage 221 again, but is not limited to this.

The second circulation passage 222 may serve as a passage through which a cooling fluid (e.g., coolant) circulates as a temperature control fluid. The second circulation passage 222 may be formed in a spiral shape inside the body 220. Alternatively, the second circulation passage 222 may be arranged so that ring-shaped passages with different radii have the same center. Each second circulation passage 222 may be in communication with each other. The second circulation passage 222 may have a larger cross-sectional area than the first circulation passage 221. A plurality of second circulation passages 222 may be formed at the same height. The second circulation passage 222 may be located below the first circulation passage 221.

The second circulation passage 222 may be connected to a cooling fluid storage unit (not shown) through a cooling fluid supply line (not shown). Cooling fluid may be stored in the cooling fluid storage unit. A cooler (not shown) may be provided within the cooling fluid storage unit. The cooler can cool the cooling fluid to a predetermined temperature. Alternatively, the cooler may be installed on the cooling fluid supply line. The cooling fluid supplied to the second circulation passage 222 through the cooling fluid supply line may circulate along the second circulation passage 222 and cool the body 220. As the body 220 cools, the support chuck 230 and the substrate W can be cooled together to maintain the substrate W at a predetermined temperature.

The support chuck 230 may be located at the top of the body 220. The support chuck 230 may be provided as a disc-shaped dielectric substance. The substrate W may be placed on the upper surface of the support chuck 230. The upper surface of the support chuck 230 may have a radius smaller than that of the substrate W, but is not limited thereto. The edge region of the substrate W may be located outside the support chuck 230, but is not limited thereto. That is, the edge region of the substrate W may be located in the ring assembly 290, but various modifications are possible. Although not shown in the drawing, the support chuck 230 may have multiple embosses. Helium gas, which is a heat transfer medium discharged from the first circulation passage 221, may be supplied to the recesses between the embosses.

Additionally, the support chuck 230 may be provided with a first electrode 231 therein. The first electrode 231 may be electrically connected to the first power source 231a. The first power source 231a may include a power source. A switch 231b may be installed between the first electrode 231 and the first power source 231a. The first electrode 231 may be electrically connected to the first power source 231a by turning the switch 231b on/off. When the switch 231b is turned on, current may be applied to the first electrode 231. Electrostatic force acts between the first electrode 231 and the substrate W due to the current applied to the first electrode 231, and the substrate W may be adsorbed to the support chuck 230 by the electrostatic force. However, the support chuck 230 is not limited to an electrostatic chuck and various modifications are possible.

The ring assembly 290 may focus the plasma onto the substrate. Although not shown in the drawing, the ring assembly 290 may be provided by combining one or more rings. For example, it may be provided as an inner ring surrounding the support chuck 230 and an outer ring surrounding the inner ring.

In addition, the support unit 200 of this embodiment may have different heat conductivity depending on the region of the substrate W to improve temperature uniformity, which will be explained with reference to FIG. 2.

The gas supply unit 300 may supply process gas into the chamber 100. The gas supply unit 300 may include a gas feeder 310, a gas supply pipe 320, and a gas storage unit 330.

The gas in the gas storage unit 330 may be supplied into the chamber 100 through the gas feeder 310 via the gas supply pipe 320. For example, the gas feeder 310 may be installed in the central portion of the upper surface of the chamber 100.

The shower head 400 may be spaced a certain distance from the top surface of the chamber 100 to the bottom to form a certain space at the top of the chamber 100. The shower head 400 may be provided in a plate shape with a constant thickness. The shower head 400 may be formed with a plurality of spray holes SH. The spray hole SH may spray the process gas into the processing space 101 by penetrating the shower head 400 in a vertical direction.

The shower head 400 may be made of a metal material, and the bottom surface of the shower head 400 may be anodized to prevent arc generation by plasma. The shower head 400 may be electrically connected to a separate power source (not shown). The power source for the shower head 400 may be provided as a high-frequency power source (e.g., high-voltage alternating current). Alternatively, the shower head 400 may be electrically grounded. The shower head 400 may be electrically connected to a power source or may be grounded to function as an electrode. For example, the shower head 400 may be provided to have the same or similar diameter as the support unit 200.

Hereinafter, the support unit 200 will be described with reference to the drawings, and the overlapping description described above will be omitted.

FIG. 2 is a diagram illustrating region A of FIG. 1.

Referring to FIG. 2, the support unit 200 of the first embodiment may include a body 220, a support chuck 230, and a first circulation passage 221. And the support chuck 230 may include a puck 230a and a block 230b.

The puck 230a may have a first thermal conductivity. For example, the first thermal conductivity may be formed by a component ratio of alumina (AL₂O₃), which has a lower thermal conductivity than the second thermal conductivity. The puck 230a may be formed with a concave groove 230ah (see FIG. 7). The concave groove 230ah may be provided so that the block 230b does not protrude from the puck 230a and the puck 230a and the block 230b are provided at the same level.

That is, the block 230b and the puck 230a may be formed at the same level. This can be achieved by providing the block 230b inside the concave groove 230ah without protruding. However, it is not limited to this. In addition, although not shown in the drawings, an emboss (not shown) may be provided on the upper surface of the puck 230a and/or block 230b with the same material and component ratio as each of the puck 230a and/or block 230b, an outer dam may be formed corresponding to the edge of the substrate W, and an inner dam may be formed by being spaced apart from the outer dam. The outer dam allows a heat transfer medium such as helium gas to stay on the bottom surface of the substrate W.

The block 230b may be provided in the concave groove 230ah and may have a second thermal conductivity different from the first thermal conductivity. For example, the second thermal conductivity may be formed by an alumina component ratio having a higher thermal conductivity than the first thermal conductivity.

The first circulation passage 221 may penetrate the support chuck 230 of the support unit 200, and may include a first heat transfer medium passage 2211 and a second heat transfer medium passage 2212, 2213, 2214 through which different fluid pressures pass or are discharged.

The pressure of the heat transfer medium may be passed through or discharged through the first heat transfer medium passage 2211 at the first fluid pressure. For example, the first fluid pressure may be supplied to a region of the substrate W where the temperature is relatively lower (e.g., the first substrate region WC, which is the center region of the substrate W, referring to FIG. 3). At this time, the first fluid pressure may be lower than the second fluid pressure.

The pressure of the heat transfer medium in the second heat transfer medium passages 2212, 2213, and 2214 is different from the first fluid pressure, and for example, the heat transfer medium may be passed through or discharged at a second fluid pressure that is higher than the first fluid pressure. As an example, the second fluid pressure may be supplied to a region of the substrate W where the temperature is relatively higher (e.g., the second substrate region WM, which is the middle region of the substrate W and/or the third substrate region WE, which is the edge region of the substrate W, referring to FIG. 3). At this time, the second fluid pressure, which is higher than the first fluid pressure, may have higher thermal conductivity than the heat transfer medium of the first fluid pressure.

As such, in this embodiment, the alumina component ratio of the puck 230a and the block 230b may be different, and the fluid pressure of the heat transfer medium supplied to the substrate W may be different. This is to ensure that the substrate is cooled with different thermal conductivities for the temperature uniformity of the substrate W.

Here, a first zone (reference numeral not shown) where the outlet of the first heat transfer medium passage 2211 is formed and a second zone (reference numeral not shown) where the outlet of the second heat transfer medium passages 2212, 2213, and 2214 is formed may be formed. The first zone may correspond to a first substrate region WC having a first temperature, and the second zone may correspond to a second substrate region WM and/or a third substrate region WE having a second temperature.

And the first heat transfer medium supply unit 221b1 may be in communication with the first heat transfer medium passage 2211 and may supply the heat transfer medium at the first fluid pressure. The second heat transfer medium supply units 221b2, 221b3, and 221b4 may be in communication with the second heat transfer medium passages 2212, 2213, and 2214 and may supply the heat transfer medium at the second fluid pressure. Here, the second fluid pressure of the second heat transfer medium supply units 221b2, 221b3, and 221b4 and the second heat transfer medium passages 2212, 2213, and 2214 may be provided such that higher fluid pressure is supplied toward the edge of the substrate W.

In addition, the first heat transfer medium supply unit 221b1 may include a first heat transfer medium supply line (reference numeral not shown) and a first heat transfer medium storage unit (reference numeral not shown). The second heat transfer medium supply units 221b2, 221b3, and 221b4 may include a second heat transfer medium supply line (reference numeral not shown) and a second heat transfer medium storage unit (reference numeral not shown).

That is, the first heat transfer medium supply unit 221b1 and the second heat transfer medium supply units 221b2, 221b3, and 221b4 are separated from each other, and the heat transfer medium can be supplied at different first and second fluid pressures. In addition, when a plurality of second heat transfer medium supply units 221b2, 221b3, and 221b4 are provided, they may be separated from each other and configured to supply fluids of different pressures. For example, a first orifice (not shown) forming a first fluid pressure may be provided in a first heat transfer medium supply line, and a second orifice forming a second fluid pressure may be provided in a second heat transfer medium supply line.

Hereinafter, a modified example of this embodiment will be described with reference to FIG. 3, and overlapping descriptions of the same configuration performing the same function will be omitted.

FIG. 3 is a diagram illustrating a support unit of a substrate processing apparatus according to a second embodiment of the present invention. With reference to FIG. 3, differences from those described using FIGS. 1 and 2 will be mainly explained.

Referring to FIG. 3, the support unit 200 of the second embodiment may include a body 220, a support chuck 230, and a first circulation passage 221, same as or similar to the first embodiment. And the support chuck 230 may include a puck 230a and a block 230b.

Meanwhile, the block 230b of the support unit 200 of the second embodiment may include a first block body 230b1 and a second block body 230b2. The first block body 230b1 may have a first thickness. The second block body 230b2 may have a second thickness greater than the first thickness.

Here, the substrate W may comprise a first substrate region WC having a first temperature, a second substrate region WM having a second temperature higher than the first temperature, and a third substrate region WE having a third temperature higher than the second temperature. For example, the first substrate region WC may be the center region of the substrate W. The second substrate region WM may be a middle region of the substrate W. The third substrate region WE may be an edge region of the substrate W.

For example, the temperature of the substrate W increases from the center to the edge, and for temperature uniformity, the exposed surface of the puck 230a may face the first substrate region WC, the first block body 230b1 may face the second substrate region WM, and the second block body 230b2 may face the third substrate region WE.

In addition, by combining the second embodiment and the first embodiment, this embodiment is the same as or similar to the first embodiment, and the first zone (not shown) where the outlet of the first heat transfer medium passage 2211 is formed may correspond to the first substrate region WC, and the second zone where the outlet of the second heat transfer medium passages 2212, 2213, 2214 is formed may correspond to the second substrate region WM and/or the third substrate region WE having a second temperature and/or a third temperature.

In addition, a plurality of first supply passages 221a1, 221a2, and 221a3 may be formed separately from each other so that the first supply passage 221a of the second embodiment is connected to the first heat transfer medium passage 2211, or is separately connected to the second heat transfer medium passages 2212, 2213, and 2214. This may be the same or similar to the first supply passage 221a of the first embodiment.

Hereinafter, a method of manufacturing the support unit 200 of the substrate processing apparatus 10 will be described with reference to the drawings.

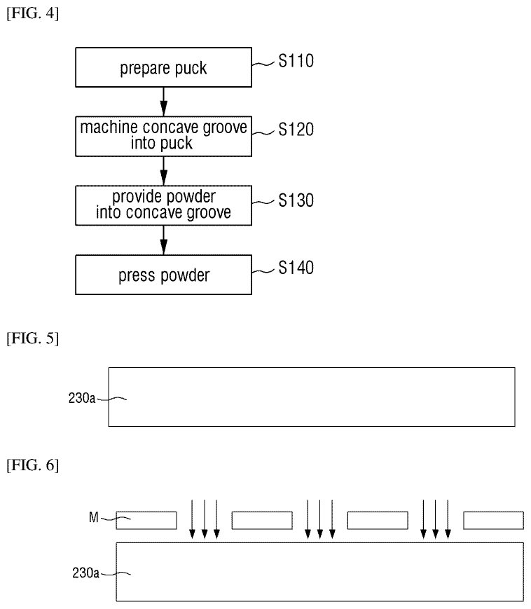

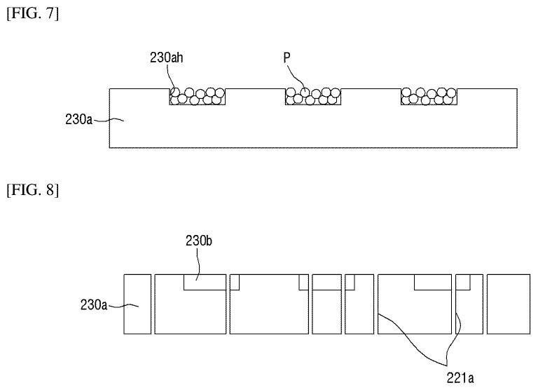

FIG. 4 is a flowchart illustrating a method of manufacturing a substrate processing apparatus according to some embodiments of the present invention. FIG. 5 is a diagram illustrating a state, in which the puck of the substrate processing apparatus according to some embodiments of the present invention is provided, and FIG. 6 is a diagram illustrating a state, in which a concave groove is machined in the puck of the substrate processing apparatus according to some embodiments of the present invention. In addition, FIG. 7 is a diagram illustrating a state, in which a block is formed on a puck of a substrate processing apparatus according to some embodiments of the present invention, and FIG. 8 is a diagram illustrating a state, in which a first circulation passage is formed in the support chuck of a substrate processing apparatus according to some embodiments of the present invention.

Referring to FIGS. 4 to 8, the method of manufacturing the substrate processing apparatus 10 may comprise providing a support chuck 230 that is provided in a processing space 101 for processing a substrate and supports the substrate W, and forming a first circulation passage 221 penetrating the support chuck 230 so that a heat transfer medium passes through the substrate W.

Here, the step of providing the support chuck 230 may comprise preparing a puck 230a having a first thermal conductivity (S110), machining a concave groove 230ah in the puck 230a (S120), and providing a powder of an alumina component ratio having a second thermal conductivity higher than the first thermal conductivity to the concave groove 230ah (S130).

First, referring to FIGS. 4 and 5, a puck 230a having a first thermal conductivity can be prepared. The first thermal conductivity may be provided by the first alumina component ratio, and have the thermal conductivity lower than the second thermal conductivity.

This is to facilitate the movement of heat by making the thermal conductivity of the puck 230a lower than the second thermal conductivity of the block 230b. In other words, the heat moves from the high side to the low side, so the heat moves from the substrate W to the block 230b, from the block 230b to the puck 230a, and then move to the second circulation passage 222 of the body 220.

Accordingly, the block 230b is formed on the side where the temperature is relatively high, and heat moves from the block 230b to the puck 230a, thereby facilitating heat exchange in the region where the temperature is high. That is, if the thermal conductivity of the block 230b is lower than that of the puck 230a, it is difficult for the heat of the block 230b to be transferred to the puck 230a, making heat exchange in the block 230b difficult, which can be prevented by the above.

Next, referring to FIGS. 4 and 6, a concave groove 230ah may be machined into the puck 230a. For example, the concave groove 230ah may be machined and formed by sanding the puck 230a. The sanding process may be performed by providing a mask M with holes corresponding to the concave grooves 230ah formed on the upper surface of the puck 230a and then spraying sand on the mask M, but is not limited to this.

Next, referring to FIGS. 4 and 7, powder P having an alumina component ratio having a second thermal conductivity higher than the first thermal conductivity may be provided to the concave groove 230ah. After providing the powder P, the block 230b can be formed by pressing the powder P in a method such as press processing.

Next, referring to FIG. 8, after providing the support chuck 230, a first circulation passage 221 and/or a first supply passage 221a penetrating the support chuck 230 may be formed so that the heat transfer medium passes through the substrate W.

Referring again to FIGS. 2 and 3, forming the first circulation passage 221 includes forming a first heat transfer medium passage 2211 connected to the first heat transfer medium supply unit 221b1 that supplies the heat transfer medium at a first fluid pressure. Simultaneously or subsequently, second heat transfer medium passages 2212, 2213, 2214 connected to the second heat transfer medium supply units 221b2, 221b3, 221b4 that supply the heat transfer medium at a second fluid pressure different from the first fluid pressure may be formed.

Although the embodiments of the present invention have been described with reference to the above and accompanying drawings, those skilled in the art to which the present invention pertains can understand that the present invention can be practiced in other specific forms without changing the technical spirit or essential features. Therefore, the embodiments described above should be understood as illustrative in all respects and not limiting.

[Reference Numeral]

| | |
|---|---|
| 10: substrate processing apparatus | 100: chamber |
| 200: support unit | 220: body |
| 230: support chuck | 230a: puck |
| 230b: block | 240: first coating layer |
| 250: bonding unit | 260: second coating layer |
| 300: gas supply unit | 400: shower head |

What is claimed is:

1. An apparatus for processing a substrate comprising:
a support unit provided in a processing space for processing a substrate and for supporting the substrate,
wherein the support unit comprises,
a puck having a first thermal conductivity and having a concave groove formed thereon; and
a block provided in the concave groove and having a second thermal conductivity different from the first thermal conductivity.

2. The apparatus of claim 1, wherein the second thermal conductivity has a higher thermal conductivity than the first thermal conductivity.

3. The apparatus of claim 2, wherein the first thermal conductivity is formed by an alumina component ratio having a lower thermal conductivity than the second thermal conductivity.

4. The apparatus of claim 2, wherein the block comprises a first block body having a first thickness, and a second block body having a second thickness greater than the first thickness.

5. The apparatus of claim 4, wherein the substrate includes a first substrate region having a first temperature, a second substrate region having a second temperature higher than the first temperature, and a third substrate region having a third temperature higher than the second temperature,
wherein an exposed surface of the puck faces the first substrate region,
wherein the first block body faces the second substrate region,
wherein the second block body faces the third substrate region.

6. The apparatus of claim 1, wherein a first circulation passage penetrating the support unit is formed to supply a heat transfer medium to the substrate,
wherein the first circulation passage comprises,
a first heat transfer medium passage through which a pressure of the heat transfer medium passes or is discharged at a first fluid pressure; and
a second heat transfer medium passage through which a pressure of the heat transfer medium passes or is discharged at a second fluid pressure different from the first fluid pressure.

7. The apparatus of claim 6, wherein the support unit comprises,
a first zone, in which an outlet of the first heat transfer medium passage is formed, and a second zone, in which an outlet of the second heat transfer medium passage is formed.

8. The apparatus of claim 6 further comprises,
a first heat transfer medium supply unit for communicating with the first heat transfer medium passage and supplying the heat transfer medium at the first fluid pressure; and
a second heat transfer medium supply unit for communicating with the second heat transfer medium passage and supplying the heat transfer medium at the second fluid pressure.

9. The apparatus of claim 1 further comprises,
a chamber, in which the processing space is formed; and
a body provided below the puck, made of aluminum, and having a second circulation passage through which a temperature control fluid moves.

10. The apparatus of claim 9 further comprises,
a gas supply unit for supplying process gas to the processing space; and
a shower head provided above the processing space and for spraying the process gas supplied from the gas supply unit into the processing space.

11. A method for manufacturing a substrate processing apparatus that performs a plasma etching process comprising:
providing a support chuck provided in a processing space for processing a substrate, and for supporting the substrate,
wherein providing the support chuck comprises,
preparing a puck having a first thermal conductivity;
machining a concave groove in the puck; and
providing a powder having an alumina component ratio having a second thermal conductivity higher than the first thermal conductivity to the concave groove.

12. The method of claim 11, wherein providing the support chuck comprises, compressing the powder after providing the powder.

13. The method of claim 11, machining the concave groove comprises,
sanding the puck.

14. The method of claim 11 further comprises,
after providing the support chuck,
forming a first circulation passage penetrating the support chuck so that a heat transfer medium passes through the substrate.

15. The method of claim 14, wherein forming the first circulation passage comprises,
forming a first heat transfer medium passage connected to a first heat transfer medium supply unit that supplies the heat transfer medium at a first fluid pressure; and
forming a second heat transfer medium passage connected to a second heat transfer medium supply unit that supplies the heat transfer medium at a second fluid pressure different from the first fluid pressure.

16. An apparatus for processing a substrate comprising:
a chamber, in which a processing space for processing a substrate is formed;
a gas supply unit for supplying process gas to the processing space;
a shower head provided above the processing space and for spraying the process gas supplied from the gas supply unit into the processing space;
a support unit provided in the processing space and for supporting the substrate;
a first heat transfer medium supply unit for supplying heat transfer medium to the support unit at a first fluid pressure; and
a second heat transfer medium supply unit for supplying the heat transfer medium to the support unit at a second fluid pressure different from the first fluid pressure,
wherein the support unit comprises,
a first circulation passage including a first heat transfer medium passage penetrating the support unit to supply a heat transfer medium to the substrate and connected to the first heat transfer medium supply unit, and a second heat transfer medium passage connected to the second heat transfer medium supply unit;
a support chuck including a puck having a first alumina component ratio, a first thermal conductivity, and a concave groove formed therein, and a block provided in the concave groove, having a second alumina component ratio different from the first alumina component ratio, and a second thermal conductivity higher than the first thermal conductivity; and
a body provided below the puck, made of aluminum, and having a second circulation passage through which a temperature control fluid moves.
